(19) United States
(12) Patent Application Publication
(10) Pub. No.: US 2006/0252247 A1
(43) Pub. Date: Nov. 9, 2006

(54) Processing apparatus for electroplating conductive bumps on organic circuit board

(76) Inventors: Shih-Ping Hsu, Hsin-chu (TW); Sao-Hsia Tang, Hsin-chu (TW); Ying-Tung Wang, Hsin-chu (TW); Wen-Hung Hu, Hsin-chu (TW); Chao-Wen Shih, Hsin-chu (TW)

Correspondence Address: Mr. Joseph A. Sawyer, Jr.;SAWYER LAW GROUP LLP, Suite 406, 2465 East Bayshore Road, Palo Alto, CA, 94303, US

(21) Appl. No.: 11/429,886

(22) Filed: May 8, 2006

(30) Foreign Application Priority Data
May 9, 2005 (TW) 094114847

(51) Int. Cl. H01L 21/44

(52) U.S. Cl. 438/612

(57) ABSTRACT

A processing apparatus for electroplating conductive bumps on an organic circuit board includes a surface cleaning unit for removing organic contaminant on the surface of conductive layer on the circuit board, a rinsing unit for rinsing the surface of conductive layer, a surface activating unit for removing a metal oxide on the surface of conductive layer, and an electroplating unit for electroplating a conductive bump on the exposing surface of the conductive layer. Thus, the conductive bumps are formed on the circuit board by electroplating. As a result, the alignment is easier, the bonding strength is reinforced, and the requirement for high density fine-pitch bumps is met

### CROSS-REFERENCE TO RELATED APPLICATIONS

This application claims benefit under 35 USC 119 of Taiwan Application No. 094114847, filed on May 9, 2005.

### FIELD OF THE INVENTION

The present invention relates to a processing apparatus for forming conductive bumps on a circuit board, and more particularly, to a processing apparatus for electroplating conductive bumps on an organic circuit board.

### BACKGROUND OF THE INVENTION

Compared to wire bonding technique, the flip-chip packaging technique introduced by IBM Corp in early 1960 is characterized by the employment of conductive bumps for electrically connecting the semiconductor chip and the substrate instead of the traditionally used gold wires. The advantages of the flip-chip packaging technique include increased package density and reduced package size. Meanwhile, the flip-chip packaging technique eliminates the need for long-length metal wires, thus reducing the resistance and increasing electrical conductivity.

In current flip-chip technique, electrode pads are disposed on the electrical surface of the semiconductor Integrated Chip (IC) chip, whereas electrical conductive pads are formed on organic circuit board, so as to conductive bumps or other conductive adhesives can be appropriately placed between the semiconductor chip and the circuit board. As a result, the chip can be disposed on the circuit board in a face-down manner, wherein the conductive bumps or conductive adhesives provide electrical I/O and mechanical connection between the chip and circuit board.

FIG. 1 illustrates a conventional flip-chip package. As shown, a plurality of conductive bumps 11 are formed on electrode pads 12 of a chip 13 and pre-solders 14 made of solders are formed on the electrical conductive pads 15 of an organic circuit board 16. Under a reflow temperature that is sufficient to fuse the pre-solders 14, the pre-solders 14 are reflowed to the corresponding conductive bumps 11, forming solder contacts 17.

Referring now to FIGS. 2A to 2C, an organic circuit board 2 used for conventional flip-chip package is shown. The circuit board 2 is formed with a plurality of electrical conductive pads 21, typically made of metal materials (e.g. copper). Thereafter, an organic insulating protective layer 22 is formed on the circuit board, such as a solder mask to protect the circuit layer on the circuit board and provide insulation. A plurality of openings 22a is formed on the insulating protective layer 22 to expose the electrical conductive pads 21 on the circuit board 2. Then, soldering materials are deposited on the electrical conductive pads 21 of the circuit board 2 by stencil printing technology and reflowed to form conductive bumps. As shown in FIG. 2A, a stencil 23 with meshes 23a is first provided on the circuit board 2, then soldering material 24 is placed on the stencil 23 and a roller is rolled back and forth on the stencil 23 to squeeze the soldering material 24 into the meshes 23a of the stencil 23; or alternatively, the soldering material 24 is sprayed into the meshes 23a of the stencil 23. As shown in FIG. 2B, after the stencil is removed, soldering dots are formed on the electrical conductive pads 21 of the circuit board 2. Thereafter, as shown in FIG. 2C, reflow of the solder is performed under a temperature sufficient to melt the soldering dots and form conductive bumps 24a on the electrical conductive pads for subsequent formation of solder contacts.

Along with the rapid improvement in various portable products in areas such as communication, network and computer, BGA (Ball Grid Array), flip chip, CSP (Chip Size Package) and MCM (Multi-Chip Module) packages having the characteristics of reduced IC area, high density and high pin counts have become the mainstream of the packaging market. These packages demand a smaller line width and pad size. However, if the pad pitch keeps reducing, the electrical conductive pads will be partially blocked by the insulating protective layer. As a result, the pad size exposed from the insulating protective layer is even smaller, which becomes an issue in subsequent alignment of conductive bumps. Furthermore, due to the space occupied by the insulating protective layer and its height, the stencil aperture in the stencil printing technology has to be reduced, which creates problems for stencil making and increases its cost. Additionally, the aperture may even be too small for the soldering material to pass through.

Moreover, the forming of soldering materials requires not only the size of the stencil to be accurate, but also the number of printing and cleaning to be taken into account. Since soldering material has a certain viscosity, when the number of printing gets larger, the residual soldering material left in the wall of the stencil holes is greater, which may result in the amount and shape of soldering material in the next printing not meeting the design specification. Thus, in actual operations, stencil must be cleaned after a certain number of usages.

Therefore, there is a need for a method for efficiently forming pre-solders on an IC package substrate that provides finer pitch and avoids poor alignment of soldering materials, weak bonding and low yield in stencil printing technique.

### SUMMARY OF THE INVENTION

In the light of forgoing drawbacks, an objective of the present invention is to provide a processing apparatus for electroplating conductive bumps on an organic circuit board, such that high density conductive bumps can be electroplated on the circuit board.

Another objective of the present invention is to provide a processing apparatus for electroplating conductive bumps on an organic circuit board that reduces difficulty in bump alignment.

Still another objective of the present invention is to provide a processing apparatus for electroplating conductive bumps on an organic circuit board that improves poor bonding of the conductive bumps on the electrical conductive pads of the circuit board.

Yet another objective of the present invention is to provide a processing apparatus for electroplating conductive bumps on an organic circuit board that allows quick and precise forming of the conductive bumps, improving reliability of the manufacturing process.

In accordance with the above and other objectives, the present invention provides a processing apparatus for electroplating conductive bumps on an organic circuit board, comprising: a surface cleaning unit for removing organic contaminant from an exposed surface of a conductive layer of the circuit board; a rinsing unit for rinsing the surface of the conductive layer; a surface activating unit for removing a metal oxide formed on the surface of the conductive layer; and an electroplating unit for electroplating conductive bumps on the surface of the conductive layer. The circuit board further comprises a plurality of electrical conductive pads. An insulating protective layer with patterned openings for exposing the electrical conductive pads is covered on the surface of the circuit board, and a photoresist having openings corresponding to the electrical conductive pads of the circuit board is formed on the conductive layer to partially expose the conductive layer overlying the electrical conductive pads. The organic contaminant and metal oxide are respectively removed from the surface of the conductive layer by the surface cleaning unit and the surface activating unit and the surface of the conductive layer is cleaned again before conductive bumps are electroplated thereon.

The processing apparatus may further comprise a post-treatment unit having a rinsing unit and a cleaning unit to rinse the circuit board with the conductive bumps thereon and remove the photoresist.

Another embodiment of the processing apparatus of the present invention comprises: a surface cleaning unit for removing organic contaminant from an exposed surface of a conductive layer of the circuit board; a first rinsing unit for rinsing the surface of the conductive layer; a first surface activating unit for removing a metal oxide formed on the surface of the conductive layer; a first electroplating unit for forming a base metal on the surface of the conductive layer; a second rinsing unit for rinsing the surface of the base metal; and a second electroplating unit for electroplating conductive bumps on the surface of the base metal.

The processing apparatus may optionally comprise a second surface activating unit for removing a metal oxide formed on the surface of the base metal, so as to facilitate subsequent formation of the conductive bumps on the surface of the base metal.

As a result, poor alignment, weak bonding and low yield in conventional stencil printing technique can thus be avoided and finer bump pitch can be achieved.

### BRIEF DESCRIPTION OF THE DRAWINGS

The present invention can be more fully understood by reading the following detailed description of the preferred embodiments, with reference made to the accompanying drawings, wherein:

FIG. 1 (PRIOR ART) is a cross-sectional diagram of a conventional flip-chip package;

FIGS. 2A to 2C (PRIOR ART) are cross-sectional diagrams illustrating forming conductive bumps on a circuit board by stencil coating;

FIG. 3 is a block diagram illustrating an embodiment of the processing apparatus for electroplating conductive bumps on organic circuit board of the present invention;

FIGS. 4A to 4D″ are cross-sectional diagrams illustrating forming conductive bumps on a circuit board of the present invention; and

FIG. 5 is a block diagram illustrating another embodiment of the processing apparatus for electroplating conductive bumps on organic circuit board of the present invention.

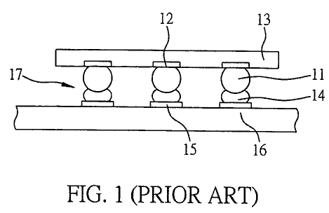

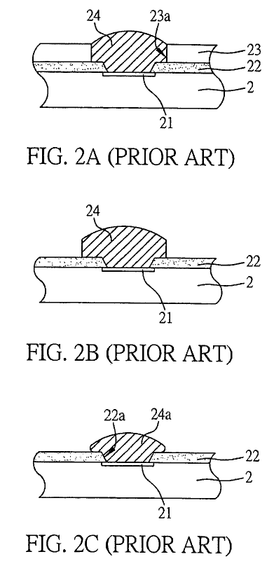

### DETAILED DESCRIPTION OF THE EMBODIMENTS

The present invention relates generally to a processing apparatus for forming conductive bumps on a circuit board, and more particularly, to a processing apparatus for electroplating conductive bumps on an organic circuit board. The following description is presented to enable one of ordinary skill in the art to make and use the invention and is provided in the context of a patent application and its requirements. Various modifications to the preferred embodiments and the generic principles and features described herein will be readily apparent to those skilled in the art. Thus, the present invention is not intended to be limited to the embodiments shown, but is to be accorded the widest scope consistent with the principles and features described herein.

### First Embodiment

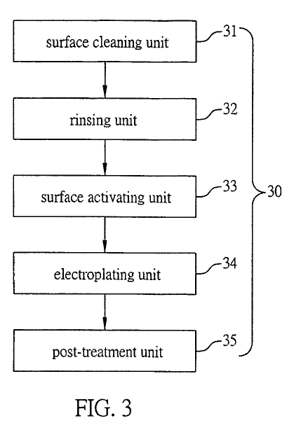

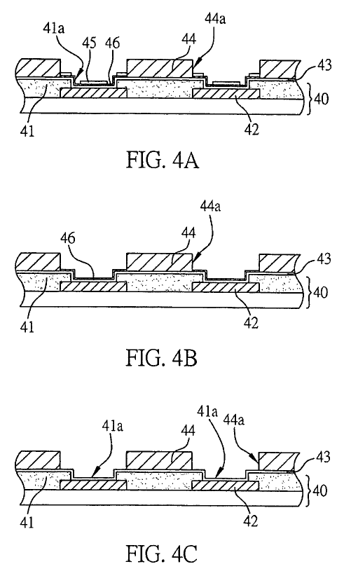

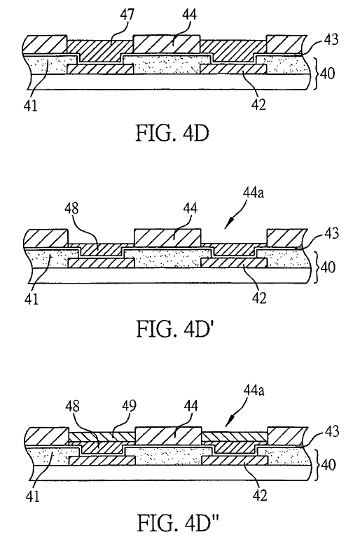

FIG. 3 shows the processing apparatus for electroplating conductive bumps on organic circuit board of the present invention. The processing apparatus mainly forms conductive bumps on circuit board. Referring to FIGS. 4A to 4D in conjunction, as shown in FIG. 4A, a circuit board 40 with electrical conductive pads 42 formed thereon is first provided, which can be a two-layer or multi-layer circuit board that has completed circuit layout. An insulating protective layer 41 with patterned openings 41a is formed on the surface of the circuit board, wherein the electrical conductive pads 42 are exposed through the patterned openings 41. The electrical conductive pads can be connected to inner circuits via conductive vias (not shown). A conductive layer 42 is formed on the insulating protective layer 41 covering the electrical conductive pads 42. A photoresist 44 is further formed on the conductive layer 42. Openings 44a corresponding to the electrical conductive pads 42 of the circuit board 41 are formed on the photoresist 44 to expose the conductive layer 43 on the surface of the electrical conductive pads 42.

The processing apparatus for forming conductive bumps comprises: a surface cleaning unit 31, a rinsing unit 32; a surface activating unit 33 and an electroplating unit 34. The surface cleaning unit 31 is used for removing organic contaminant 45 on the surface of the conductive layer 43 of the circuit board 40, FIG. 4A shows the structure before the organic contaminant 45 are removed and FIG. 4B shows the structure after the organic contaminant are removed from the circuit board 40. The surface cleaning unit 31 is a cleanser with surfactant to remove the organic contaminant 45 on the surface of the conductive layer 43. The rinsing unit 32 is used to rinse the surface of the conductive layer 43. The surface activating unit 33 is used to remove a metal oxide 46 formed on the surface of the conductive layer 43, as shown in FIG. 4C. The electroplating unit 34 is used to perform electroplating on the exposed surface of the conductive layer 43 to form conductive bumps 47. The conductive bumps can be copper, tin, lead, nickel, gold, silver, bismuth or their alloy, as shown in FIG. 4D.

The processing apparatus 30 may further comprise a post-treatment unit 35 having a rinsing unit and cleaning unit, so as to make a final cleaning of the circuit board 40 formed with the conductive bumps 47, as well as to remove the photoresist on the surface of the circuit board.

Since the conductive bumps 47 are electroplated on the electrical conductive pads 42 through the conductive layer 43, so before the conductive bumps 47 are formed, the surface activating unit 33 must be used to remove the metal oxide 46 on the surface of the conductive layer 43, such that the conductive layer 43 has a clean surface for subsequent forming of the conductive bumps 47. In addition, the surface activating unit 33 further comprises the effect of prewetting the circuit board 40, so as to increase the wetting of the surface of the conductive layer 43 of the circuit board to facilitate formation of the conductive bumps 47 thereon.

### Second Embodiment

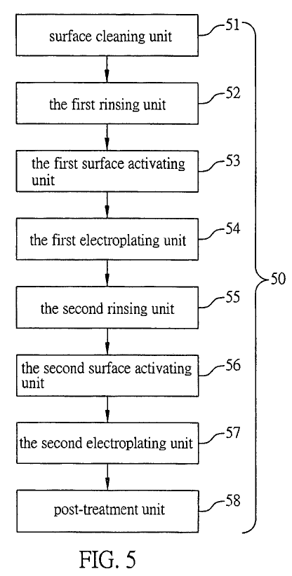

FIG. 5 shows another embodiment of the processing apparatus of the present invention. The difference of this embodiment with the previous one is in that a base metal is first electroplated on the top of the electrical conductive pads 42 of the circuit board 40, and conductive bumps are then formed on the base metal.

The processing apparatus 50 in this embodiment comprises: a surface cleaning unit 51, a first rinsing unit 52; a first surface activating unit 53; a first electroplating unit 54; a second rinsing unit 55; a second surface activating unit 56 and a second electroplating unit 57. The surface cleaning unit 51 is a cleanser with surfactant to remove the organic contaminant 45 on the surface of the exposed conductive layer 43. The first rinsing unit 52 is used to rinse the surface of the conductive layer 43 to remove residuals from the last process. The first surface activating unit 53 is used to remove a metal oxide 46 formed on the surface of the conductive layer 43. The first electroplating unit 54 is used to form a base metal 48 on the surface of the conductive layer 43, as shown in FIG. 4D′. The second rinsing unit 55 is used to rinse the surface of the base metal 48 to remove residuals from the last process. The second surface activating unit 56 is used to remove a metal oxide 46 formed on the surface of the base metal 48. The second surface activating unit 56 can be selectively used. If the base metal 48 is chemically active, i.e. oxide may easily formed thereon, then the second surface activating unit 56 can be used; else if the base metal 48 is chemically inactive, i.e. oxide may not easily formed thereon, then the second surface activating unit 56 can be omitted. The second electroplating unit 57 is used to form conductive bumps 49 on the surface of the base metal 48, as shown in FIG. 4D″.

The processing apparatus 50 may further comprise a post-treatment unit 58 having a rinsing unit and cleaning unit, so as to make a final cleaning of the circuit board 40, as well as to remove the photoresist 44 on the surface of the circuit board 40.

The processing apparatus 50 first forms the base metal 48 on the electrical conductive pads 42 of the circuit board 40 through the conductive layer 43 by electroplating, then forms the conductive bumps 49 by electroplating. Before the first electroplating unit is used, metal oxide is first removed using the first surface activating unit 53. After the base metal 48 is formed, the second surface activating unit 56 for removing metal oxide on the surface of the base metal 48 can be selectively used. Thereafter, the second electroplating unit 57 is used to form the conductive bumps 49 on the base metal 48.

The present invention employs exposure-development method for forming openings on the photoresist. The resulting openings are formed on the top of the electrical conductive pads of the circuit board, such that the conductive layer is used as a conductor so as to form the conductive bumps over the electrical conductive pads, or the double-layer structure consisting of the base metal and the conductive bumps by electroplating. According, the present invention reduces the difficulty in alignment of stencil printing in the prior art. Additionally, conductive bumps formed by electroplating has a stronger bonding than the prior art, and that finer pitch between the bumps can be achieved.

Moreover, conductive bumps can be quickly and precisely formed on the circuit board using the processing apparatus of the present invention, thereby enhancing processing reliability.

Although the present invention has been described in accordance with the embodiments shown, one of ordinary skill in the art will readily recognize that there could be variations to the embodiments and those variations would be within the spirit and scope of the present invention. Accordingly, many modifications may be made by one of ordinary skill in the art without departing from the spirit and scope of the appended claims.

What is claimed is:

1. A processing apparatus for electroplating conductive bumps on an organic circuit board, comprising:
a surface cleaning unit for removing organic contaminant from an exposed surface of a conductive layer of the circuit board;
a rinsing unit for rinsing the surface of the conductive layer;
a surface activating unit for removing a metal oxide formed on the surface of the conductive layer; and
an electroplating unit for electroplating conductive bumps on the surface of the conductive layer.

2. The processing apparatus of claim 1, wherein the circuit board further comprises a plurality of electrical conductive pads for the conductive layer and the conductive bumps to be formed thereon.

3. The processing apparatus of claim 2, wherein the circuit board further comprises an insulating protective layer with patterned openings for exposing the electrical conductive pads, the conductive layer being formed on the insulating protective layer and covering the electrical conductive pads, and a photoresist having openings corresponding to the electrical conductive pads of the circuit board being formed on the conductive layer to partially expose the conductive layer overlying the electrical conductive pads.

4. The processing apparatus of claim 1, further comprising a post-treatment unit.

5. The processing apparatus of claim 4, wherein the post-treatment unit comprises a rinsing unit and a cleaning unit.

6. The processing apparatus of claim 1, wherein the surface cleaning unit comprises a cleanser to remove the organic contaminant on the surface of the conductive layer of the circuit board.

7. The processing apparatus of claim 6, wherein the cleanser comprises a surfactant.

8. The processing apparatus of claim 1, wherein the conductive bumps are selected from the group consisting of copper, tin, lead, nickel, gold, silver, bismuth and their alloys.

9. A processing apparatus for electroplating conductive bumps on an organic circuit board, comprising:
a surface cleaning unit for removing organic contaminant from an exposed surface of a conductive layer of the circuit board;
a first rinsing unit for rinsing the surface of the conductive layer;
a first surface activating unit for removing a metal oxide formed on the surface of the conductive layer;
a first electroplating unit for forming a base metal on the surface of the conductive layer;
a second rinsing unit for rinsing the surface of the base metal; and
a second electroplating unit for electroplating conductive bumps on the surface of the base metal.

10. The processing apparatus of claim 9, further comprising a second surface activating unit for removing a metal oxide formed on the surface of the base metal.

11. The processing apparatus of claim 9, wherein the circuit board further comprises a plurality of electrical conductive pads for the conductive layer and the conductive bumps to be formed thereon.

12. The processing apparatus of claim 11, wherein the circuit board further comprises an insulating protective layer with patterned openings for exposing the electrical conductive pads, the conductive layer being formed on the insulating protective layer and covering the electrical conductive pads, and a photoresist having openings corresponding to the electrical conductive pads of the circuit board being formed on the conductive layer to partially expose the conductive layer overlying the electrical conductive pads.

13. The processing apparatus of claim 9, further comprising a post-treatment unit.

14. The processing apparatus of claim 13, wherein the post-treatment unit comprises a rinsing unit and a cleaning unit.

15. The processing apparatus of claim 9, wherein the first surface cleaning unit comprises a cleanser to remove the organic contaminant on the surface of the conductive layer of the circuit board.

16. The processing apparatus of claim 15, wherein the cleanser comprises a surfactant.

17. The processing apparatus of claim 9, wherein the conductive bumps are selected from the group consisting of copper, tin, lead, nickel, gold, silver, bismuth and their alloys.
